(19) United States
(12) Patent Application Publication
(10) Pub. No.: US 2014/0239329 A1
(43) Pub. Date: Aug. 28, 2014

(54) COLOR FILTER SUBSTRATE, ELECTROOPTIC DEVICE, ELECTROOPTIC DEVICE MANUFACTURING METHOD, AND ELECTRONIC APPARATUS

(71) Applicant: Seiko Epson Corporation, Tokyo (JP)

(72) Inventor: Masayuki Wada, Matsumoto-shi (JP)

(73) Assignee: Seiko Epson Corporation, Tokyo (JP)

(21) Appl. No.: 14/178,602

(22) Filed: Feb. 12, 2014

(30) Foreign Application Priority Data
Feb. 25, 2013 (JP) 2013-034262

(51) Int. Cl. H01L 33/58; G02B 5/22

(52) U.S. Cl. CPC H01L 33/58; G02B 5/22
USPC 257/98; 359/885

(57) ABSTRACT

A color filter substrate includes a second base material, a stopper film provided on the second base material, an insulating film including color filter grooves provided on the stopper film, and color filters provided so as to embed the color filter grooves.

### BACKGROUND

1. Technical Field

The present invention relates to a color filter substrate, an electrooptic device, an electrooptic device manufacturing method, and an electronic apparatus.

2. Related Art

Known has been an active driving-type liquid crystal device including transistors as elements for switching-controlling pixel electrodes for respective pixels, for example, as one of the above-mentioned electrooptic device. The liquid crystal device is used as a light valve of a direct view-type display or a projector, for example.

A method of manufacturing a color filter substrate included in the liquid crystal device is as follows as described in JP-A-8-146214, for example. That is, openings before forming color filters are formed on a glass substrate by using, as a mask, a black matrix formed on the substrate by patterning, by using a photolithography technique and an etching technique. Next, the color filters are formed in the openings so as to obtain the color filter substrate.

However, the depths of the openings in a substrate surface fluctuate due to a configuration of a manufacturing device when etching is performed. Because of this, when the color filters are embedded in the openings, the color filters project from the substrate and a gap between an element substrate and a counter substrate fluctuates. As a result, there arises a problem that transmittance and the like are influenced.

### SUMMARY

An advantage of some aspects of the invention is to solve at least a part of the issues mentioned above and can be realized in the following modes or Application Examples.

### Application Example 1

A color filter substrate according to Application Example 1 includes a substrate, a stopper film that is provided on the substrate, an insulating film that has opening holes provided on the stopper film, and color filters that are provided so as to embed the opening holes.

According to Application Example 1, the stopper film is provided on the substrate. Therefore, when the opening holes are formed on the insulating film on the stopper film, etching can be substantially stopped at the stopper film based on a selection ratio between the insulating film and the stopper film. Therefore, a plurality of opening holes can be formed to have a predetermined depth. With this, when the color filters are formed in the opening holes, the color filters can be prevented from projecting from the insulating film. This can make the gap between substrates uniform over the entire substrate. As a result, influence on transmittance and the like can be suppressed.

### Application Example 2

In the color filter substrate according to above Application Example 1, it is preferable that a space between the substrate and the stopper film in a normal line direction of the substrate be made different in accordance with colors of the color filters.

According to Application Example 2, the space between the substrate and the stopper film is made different in accordance with the colors so as to control the depths of the opening holes. Therefore, optical path lengths of the respective color filters can be changed to predetermined optical path lengths. This can increase intensity of each color, thereby improving hue.

### Application Example 3

In the color filter substrate according to above Application Example 1 or 2, it is preferable that the stopper film be provided on regions which do not overlap with the opening holes when seen from the above.

According to Application Example 3, the stopper film is not provided on the regions that overlap with the opening holes. This can suppress lowering of an aperture ratio due to the stopper film.

### Application Example 4

In the color filter substrate according to above Application Example 1, 2 or 3, it is preferable that a light-shielding film be provided on the insulating film.

According to Application Example 4, the light-shielding film is provided on the insulating film, that is, the regions excluding the opening holes. This can suppress entrance of oblique light into the color filters.

### Application Example 5

An electrooptic device according to Application Example 5 includes a first substrate, a second substrate that is arranged so as to oppose to the first substrate, an electrooptic layer that is held between the first substrate and the second substrate, a stopper film that is provided on the first substrate or the second substrate, an insulating film that has opening holes provided on the stopper film, and color filters that are provided so as to embed the opening holes.

According to Application Example 5, the stopper film is provided on the substrate. Therefore, when the opening holes are formed on the insulating film on the stopper film, etching can be substantially stopped at the stopper film based on a selection ratio between the insulating film and the stopper film. Accordingly, the plurality of opening holes can be formed to have a predetermined depth. With this, when the color filters are formed in the opening holes, the color filters can be prevented from projecting from the insulating film. This can make the gap between substrates uniform over the entire substrate. As a result, influence on transmittance and the like can be suppressed.

### Application Example 6

In the electrooptic device according to above Application Example 5, it is preferable that a space between the first substrate or the second substrate and the stopper film in a normal line direction of the first substrate or the second substrate be made different in accordance with colors of the color filters.

According to Application Example 6, the space between the substrate and the stopper film is made different in accordance with the colors so as to control the depths of the opening holes. Therefore, optical path lengths of the respective color filters can be changed to predetermined optical path lengths. This can increase intensity of each color, thereby improving hue.

### Application Example 7

In the electrooptic device according to above Application Example 5 or 6, it is preferable that the stopper film be provided on regions which do not overlap with the opening holes when seen from the above.

According to Application Example 7, the stopper film is not provided on the regions that overlap with the opening holes. This can suppress lowering of an aperture ratio due to the stopper film.

### Application Example 8

In the electrooptic device according to above Application Example 5, 6 or 7, it is preferable that a light-shielding film be provided on the insulating film.

According to Application Example 8, the light-shielding film is provided on the insulating film, that is, the regions excluding the opening holes. This can suppress entrance of oblique light into the color filters.

### Application Example 9

An electrooptic device manufacturing method according to Application Example 9, which is a method of manufacturing an electrooptic device including a first substrate, a second substrate that is arranged so as to oppose to the first substrate, and an electrooptic layer that is held between the first substrate and the second substrate, includes forming a stopper film on the first substrate or the second substrate, forming an insulating film on the stopper film, forming opening holes by performing etching processing on the insulating film on a region which overlaps with the stopper film when seen from the above by using a resist pattern as a mask, removing the stopper film on at least regions that overlap with the opening holes when seen from the above, and embedding color filters in the opening holes.

According to Application Example 9, the stopper film is formed on the substrate. Therefore, when the opening holes are formed on the insulating film on the stopper film, etching can be substantially stopped at the stopper film based on a selection ratio between the insulating film and the stopper film. Accordingly, the plurality of opening holes can be formed to have a predetermined depth. With this, when the color filters are formed in the opening holes, the color filters can be prevented from projecting from the insulating film. This can make the gap between substrates uniform over the entire substrate. As a result, influence on the transmittance and the like can be suppressed.

### Application Example 10

In the electrooptic device manufacturing method according to above Application Example 1, it is preferable that the stopper film be formed on regions which overlap with the opening holes when seen from the above by patterning in the forming of the stopper film.

According to Application Example 10, etching can be stopped at a predetermined depth by the patterned stopper film when the opening holes are formed. Further, the stopper film is exposed in the opening holes after the opening holes are formed. Therefore, the stopper film influencing on an aperture ratio can be removed, thereby improving the aperture ratio.

### Application Example 11

In the electrooptic device manufacturing method according to above Application Example 9 or 10, it is preferable that the stopper film be formed such that a space between the first substrate or the second substrate and the stopper film in a normal line direction of the first substrate or the second substrate be made different in accordance with colors of the color filters in the forming of the stopper film.

According to Application Example 11, the space between the substrate and the stopper film is made different in accordance with the colors so as to control the depths of the opening holes. Therefore, optical path lengths of the respective color filters can be changed to predetermined optical path lengths. This can increase intensity of each color, thereby improving hue.

### Application Example 12

In the electrooptic device manufacturing method according to above Application Example 9, 10 or 11, it is preferable that the method further include forming a light-shielding film on the insulating film after the forming of the insulating film.

According to Application Example 12, the light-shielding film is provided on the insulating film, that is, the regions excluding the opening holes. This can suppress entrance of oblique light into the color filters.

### Application Example 13

An electronic apparatus according to Application Example 13 includes the electrooptic device according to above-mentioned Application Example 9, 10, 11 or 12.

According to Application Example 13, the electronic apparatus includes the electrooptic device. Therefore, the electronic apparatus that makes it possible to improve display quality such as the transmittance can be provided.

### BRIEF DESCRIPTION OF THE DRAWINGS

The invention will be described with reference to the accompanying drawings, wherein like numbers reference like elements.

FIG. 1 is a schematic plan view illustrating a configuration of a liquid crystal device according to a first embodiment.

FIG. 2 is a schematic cross-sectional view illustrating the liquid crystal device cut along a line II-II in FIG. 1.

FIG. 3 is an equivalent circuit diagram illustrating an electric configuration of the liquid crystal device.

FIG. 4 is a schematic cross-sectional view illustrating the configuration of the liquid crystal device.

FIG. 5 is a schematic cross-sectional view illustrating configurations of a counter substrate constituting the liquid crystal device and a color filter substrate constituting the counter substrate.

FIG. 6 is a flowchart illustrating a method of manufacturing the liquid crystal device in the order of processes.

FIGS. 7A to 7C are schematic cross-sectional views illustrating a part of the method of manufacturing liquid crystal device.

FIGS. 8D to 8F are schematic cross-sectional views illustrating a part of the method of manufacturing liquid crystal device.

FIGS. 9A and 9B are schematic views illustrating a configuration of a projection-type display apparatus including the liquid crystal device.

FIG. 10 is a schematic cross-sectional view illustrating configurations of a counter substrate constituting a liquid crystal device and a color filter substrate constituting the counter substrate according to a second embodiment.

FIGS. 11A to 11C are schematic cross-sectional views illustrating a method of manufacturing the counter substrate in the order of processes in the second embodiment.

FIGS. 12D to 12F are schematic cross-sectional views illustrating the method of manufacturing the counter substrate in the order of processes.

FIG. 13 is a schematic cross-sectional view illustrating a configuration of a color filter substrate according to a variation.

FIG. 14 is a schematic cross-sectional view illustrating a configuration of a liquid crystal device according to another variation.

### DESCRIPTION OF EXEMPLARY EMBODIMENTS

Hereinafter, described are embodiments to which the invention is embodied with reference to the drawings. The drawings to be used are illustrated in an enlarged or contracted manner appropriately such that portions to be described are made into states of being recognized.

In the following embodiments, for example, an expression “on a substrate” indicates the case where a constituent component is arranged on the substrate in a contact manner, the case where a constituent component is arranged on the substrate through another constituent component, or the case where a part of a constituent component is arranged on the substrate in a contract manner and another part of it is arranged through another constituent component.

In the embodiment, a liquid crystal device is described by using an active matrix-type liquid crystal device including thin film transistors (TFT) as switching elements of pixels as an example. For example, the liquid crystal device can be preferably used as a light modulator (liquid crystal light valve) of a projection-type display apparatus (liquid crystal projector).

### First Embodiment

### Configuration of Liquid Crystal Device

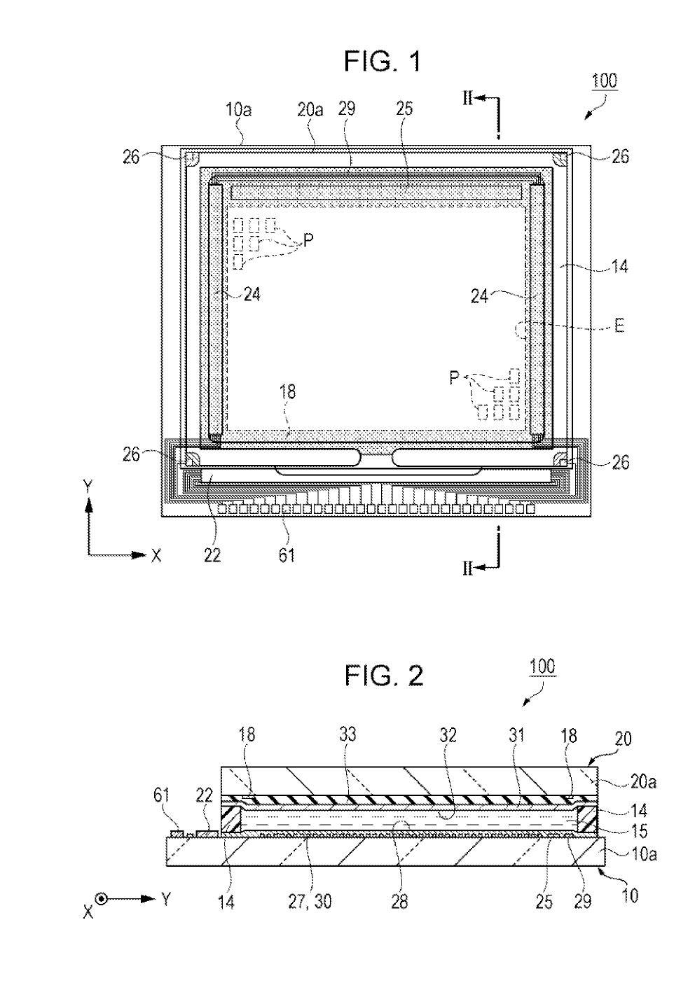

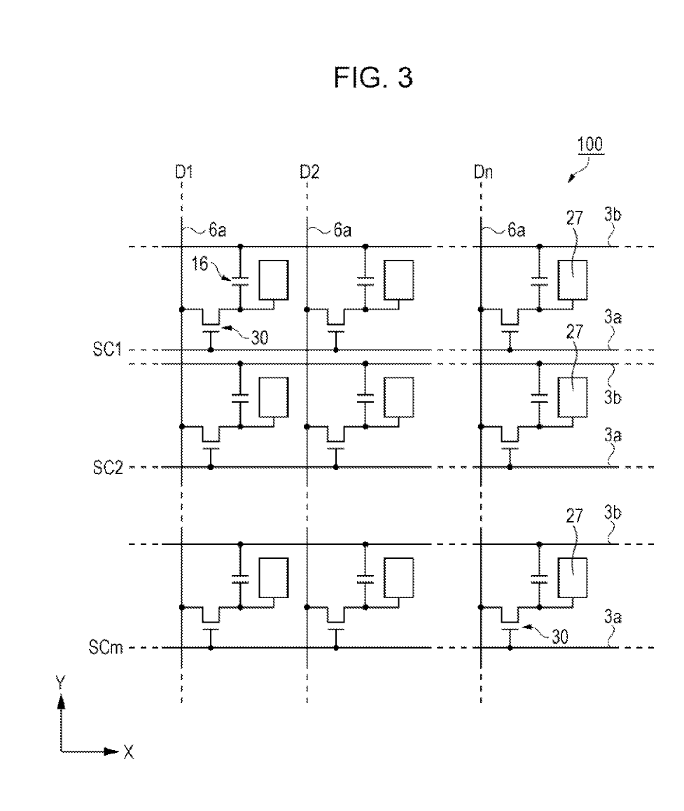

FIG. 1 is a schematic plan view illustrating a configuration of a liquid crystal device. FIG. 2 is a schematic cross-sectional view illustrating the liquid crystal device cut along a line II-II in FIG. 1. FIG. 3 is an equivalent circuit diagram illustrating an electric configuration of the liquid crystal device. Hereinafter, described is the configuration of the liquid crystal device with reference to FIG. 1 to FIG. 3.

As illustrated in FIG. 1 and FIG. 2, a liquid crystal device 100 in the embodiment includes an element substrate 10 (first substrate) and a counter substrate 20 (second substrate) that are arranged so as to oppose to each other, and a liquid crystal layer 15 as an electrooptic layer that is held between the pair of substrates. As a first base material 10a constituting the element substrate 10 and a second base material 20a constituting the counter substrate 20, a transparent substrate such as a glass substrate or a quartz substrate is used, for example.

The element substrate 10 is larger than the counter substrate 20 and both the substrates are bonded to each other through a sealing member 14 arranged along an outer circumference of the counter substrate 20. The liquid crystal is injected into between the element substrate 10 and the counter substrate 20 so as to constitute the liquid crystal layer 15 at the inner side of the sealing member 14 provided in a frame form when seen from the above. The liquid crystal has positive or negative dielectric anisotropy. As the sealing member 14, employed is an adhesive made of a thermosetting or ultraviolet-curable epoxy resin, for example. A spacer (not illustrated) for keeping a constant space between the pair of substrates is mixed into the sealing member 14.

A display region E is provided at the inner side than the inner edge of the sealing member 14. A plurality of pixels P are aligned on the display region E. The display region E may include dummy pixels arranged so as to surround the plurality of pixels P in addition to the plurality of pixels P contributing to display. Although not illustrated in FIG. 1 and FIG. 2, a light-shielding film (black matrix; BM) defining the plurality of pixels P two-dimensionally on the display region E is also provided on the counter substrate 20.

A data line driving circuit 22 is provided between the sealing member 14 along one side of the element substrate 10 and the one side. Further, a test circuit 25 is provided between the sealing member 14 along another side opposing to the one side of the element substrate 10 and the display region E. In addition, scan line driving circuits 24 are provided between the sealing member 14 along other two sides that are orthogonal to the one side and oppose to each other and the display region E. A plurality of wirings 29 connecting the two scan line driving circuits 24 are provided between the sealing member 14 along another side opposing to the one side and the test circuit 25.

A light-shielding film 18 (parting portion) is provided between the sealing member 14 arranged on the counter substrate 20 in the frame form and the display region E. For example, the light-shielding film 18 is made of a metal or metal oxide having light shielding property. The inner side of the light-shielding film 18 corresponds to the display region E having the plurality of pixels P. It is to be noted that although not illustrated in FIG. 1, the light-shielding film defining the plurality of pixels P two-dimensionally is also provided on the display region E.

The wirings connected to the data line driving circuit 22 and the scan line driving circuits 24 are connected to a plurality of external connection terminals 61 aligned along the one side. In the following description, the direction along the one side is defined as an X direction and the direction along the other two sides that are orthogonal to the one side and oppose to each other is defined as a Y direction.

As illustrated in FIG. 2, pixel electrodes 27 having light transmissivity, thin film transistors (TFTs) (hereinafter, referred to as “TFT 30”) as switching elements, signal wirings, and an alignment layer 28 covering them are formed on the surface of the first base material 10a at the liquid crystal layer 15 side. The pixel electrodes 27 and the TFTs 30 are provided for the respective pixels P.

Further, employed is a light-shielding configuration for preventing occurrence of a problem that light is incident on the semiconductor layers on the TFTs 30 and switching operations thereof become unstable. The element substrate 10 in the invention includes at least the pixel electrodes 27, the TFTs 30, and the alignment layer 28.

The light-shielding film 18, a flattening layer 33, a counter electrode 31, and an alignment layer 32 are provided on the surface of the counter substrate 20 at the liquid crystal layer 15 side. The flattening layer 33 is formed so as to cover the light-shielding film 18. The counter electrode 31 is provided so as to cover the flattening layer 33. The alignment layer 32 covers the counter electrode 31. The counter substrate 20 in the invention includes at least the counter electrode 31 and the alignment layer 32.

As illustrated in FIG. 1, the light-shielding film 18 is provided at a position surrounding the display region E and overlapping with the scan line driving circuits 24 and the test circuit 25 two-dimensionally (not illustrated). The light-shielding film 18 blocks light that is incident on the peripheral circuits including these driving circuits from the counter substrate 20 side so as to prevent malfunction of the peripheral circuits due to the light. In addition, the light-shielding layer 18 blocks light such that unnecessary stray light is not incident on the display region E so as to ensure high contrast to display on the display region E.

The flattening layer 33 is made of an inorganic material such as silicon oxide, for example, has light transmissivity, and is provided so as to cover the light-shielding film 18. As a method of forming the flattening layer 33, for example, a film formation method by using a plasma chemical vapor deposition (CVD) technique is exemplified.

The counter electrode 31 is formed by a transparent conductive film made of indium tin oxide (ITO), for example. The counter electrode 31 covers the flattening layer 33 and is electrically connected to the wirings at the element substrate 10 side by vertical conducting portions 26 provided in four corners of the counter substrate 20, as illustrated in FIG. 1.

The alignment layer 28 covering the pixel electrodes 27 and the alignment layer 32 covering the counter electrode 31 are selected based on optical design of the liquid crystal device 100. For example, as the alignment layer 28 and the alignment layer 32, used is an inorganic alignment layer obtained by forming a film of an inorganic material such as silicon oxide (SiOx) by using a vapor deposition method and performing substantially vertical alignment processing on liquid crystal molecules having negative dielectric anisotropy.

The liquid crystal device 100 is of a transmissive type and employs optical design of a normally white mode or a normally black mode. In the normally white mode, the transmittance of the pixels P when a voltage is not applied thereto is larger than the transmittance of the pixels P when a voltage is applied thereto and bright display is made. In the normally black mode, the transmittance of the pixels P when a voltage is not applied thereto is smaller than the transmittance of the pixels P when a voltage is applied thereto and dark display is made. Polarization elements are arranged at the light incident side and the light output side in accordance with the optical design for use.

As illustrated in FIG. 3, the liquid crystal device 100 includes at least a plurality of scan lines 3a, a plurality of data lines 6a, and a plurality of capacitor lines 3b. The scan lines 3a and the data lines 6a are insulated from and orthogonal to each other on the display region E. The direction in which the scan lines 3a extend corresponds to the X direction and the direction in which the data lines 6a extend corresponds to the Y direction.

The pixel electrodes 27, the TFTs 30, and capacitor elements 16 are provided on regions partitioned by those signal lines such as the scan lines 3a, the data lines 6a and the capacitor lines 3b so as to constitute pixel circuits of the pixels P.

The scan lines 3a are electrically connected to the gates of the TFTs 30, and the data lines 6a are electrically connected to data line-side source-drain regions (source regions) of the TFTs 30. The pixel electrodes 27 are electrically connected to pixel electrode-side source-drain regions (drain regions) of the TFTs 30.

The data lines 6a are connected to the data line driving circuit 22 (see FIG. 1). The data lines 6a supply image signals D1, D2, . . . , Dn that are supplied from the data line driving circuit 22 to the respective pixels P. The scan lines 3a are connected to the scan line driving circuits 24 (see FIG. 1). The scan lines 3a supply scan signals SC1, SC2, . . . , SCm that are supplied from the scan line driving circuits 24 to the respective pixels P.

The image signals D1 to Dn that are supplied to the data lines 6a from the data line driving circuit 22 may be supplied in this order in a line sequential manner or may be supplied to groups each configured of a plurality of data lines 6a adjacent to one another. The scan line driving circuits 24 supply the scan signals SC1 to SCm to the scan lines 3a at a predetermined timing.

The liquid crystal device 100 is configured as follows. That is, if the TFTs 30 as the switching elements are made into ON states for a certain period of time only with the input of the scan signals SC1 to SCm, the image signals D1 to Dn that are supplied from the data lines 6a are written into the pixel electrodes 27 at a predetermined timing. Then, the image signals D1 to Dn at a predetermined level, which have been written into the liquid crystal layer 15 through the pixel electrodes 27, are held between the pixel electrodes 27 and the counter electrode 31 for a certain period of time. Note that the counter electrode 31 is arranged so as to oppose to the pixel electrodes 27 through the liquid crystal layer 15.

In order to prevent the held image signals D1 to Dn from leaking, the capacitor elements 16 are connected in parallel with the liquid crystal capacitor formed between the pixel electrodes 27 and the counter electrode 31. The capacitor elements 16 are provided between the pixel electrode-side source-drain regions of the TFTs 30 and the capacitor lines 3b. The capacitor elements 16 have dielectric layers between two capacitor electrodes.

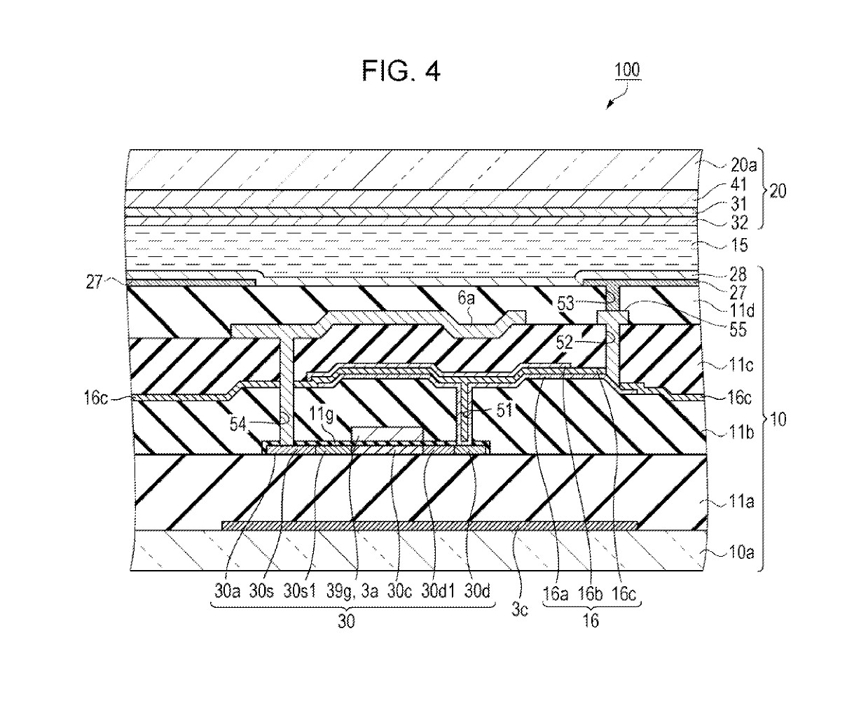

FIG. 4 is a schematic cross-sectional view illustrating a configuration of the liquid crystal device. Hereinafter, the configuration of the liquid crystal device is described with reference to FIG. 4. FIG. 4 illustrates cross-sectional positional relation of the respective constituent components in scales by which they can be illustrated clearly.

As illustrated in FIG. 4, the liquid crystal device 100 includes the element substrate 10 as one substrate of a pair of substrates and the counter substrate 20 as the other substrate that is arranged so as to oppose to the element substrate 10. As described above, the first base material 10a constituting the element substrate 10 and the second base material 20a constituting the counter substrate 20 are formed by a quartz substrate or the like, for example.

A lower side light-shielding film 3c made of titanium (Ti), chromium (Cr), or the like is formed on the first base material 10a. The lower side light-shielding film 3c is patterned in a grid form two-dimensionally and defines opening regions of the respective pixels. It is to be noted that the lower side light-shielding film 3c may be made to function as a part of the scan lines 3a. A foundation insulting layer 11a formed by a silicon oxide film or the like is formed on the first base material 10a and the lower side light-shielding film 3c.

The TFTs 30, the scan lines 3a, and the like are formed on the foundation insulting layer 11a. The TFTs 30 have a lightly doped drain (LDD) structure, for example, and include semiconductor layers 30a, gate insulating films 11g, and gate electrodes 30g. The semiconductor layers 30a are made of polysilicon or the like. The gate insulating films 11g are formed on the semiconductor layers 30a. The gate electrodes 30g are formed on the gate insulating films 11g and are formed by polysilicon films or the like. As described above, the scan lines 3a also function as the gate electrodes 30g.

N-type impurity ions such as phosphor (P) ions, for example, are injected into the semiconductor layers 30a, so that N-type TFTs 30 are formed. To be specific, each semiconductor layer 30a includes a channel region 30c, a data line-side LDD region 30s1, a data line-side source-drain region 30s, a pixel electrode-side LDD region 30d1, and a pixel electrode-side source-drain region 30d.

The channel region 30c is doped with P-type impurity ions such as boron (B) ions. Other regions (30s1, 30s, 30d1, 30d) are doped with the N-type impurity ions such as the phosphor (P) ions. In this manner, the TFTs 30 are formed as the N-type TFTs.

A first insulating interlayer 11b formed by a silicon oxide film or the like is formed on the gate electrodes 30g, the foundation insulating layer 11a, and the scan lines 3a. The capacitor elements 16 are provided on the first insulating interlayer 11b. To be specific, first capacitor electrodes 16a as pixel potential-side capacitor electrodes and a part of capacitor lines 3b (second capacitor electrodes 16b) as fixed potential-side capacitor electrodes are arranged so as to oppose to each other through a dielectric film 16c. With this, the capacitor elements 16 are formed. Note that the first capacitor electrodes 16a are electrically connected to the pixel electrode-side source-drain regions 30d of the TFTs 30 and the pixel electrodes 27.

For example, the capacitor lines 3b (second capacitor electrodes 16b) are made of a single metal, alloy, metal silicide, polysilicide, or a laminated body thereof containing at least one of metals having a high melting point, such as titanium (Ti), chromium (Cr), tungsten (W), tantalum (Ta), and molybdenum (Mo). Alternatively, the capacitor lines 3b (second capacitor electrodes 16b) can be formed by an aluminum (Al) film.

The first capacitor electrodes 16a are formed by a conductive polysilicon film, for example, and function as pixel electrode-side capacitor electrodes of the capacitor elements 16. Note that the first capacitor electrodes 16a may be formed by a monolayer film or a multi-layer film containing a metal or alloy in the same manner as the capacitor lines 3b. In addition to the function as the pixel potential-side capacitor electrodes, the first capacitor electrodes 16a have a function of relaying the pixel electrodes 27 and the pixel electrode-side source-drain regions 30d (drain regions) of the TFTs 30 through contact holes CNT 52, relay layers 55, contact holes CNT53, and contact holes CNT51.

The data lines 6a are formed on the capacitor elements 16 through a second insulating interlayer 11c. The data lines 6a are electrically connected to the data line-side source-drain regions 30s (source regions) of the semiconductor layers 30a through contact holes CNT 54. The contact holes CNT 54 are opened on the first insulating interlayer 11b and the second insulating interlayer 11c.

The pixel electrodes 27 are formed on the data lines 6a through a third insulating interlayer 11d. The pixel electrodes 27 are connected to the first capacitor electrodes 16a through the contact holes CNT52 and CNT53 and the relay layers 55. The contact holes CNT52 and CNT53 are opened on the second insulating interlayer 11c and the third insulating interlayer 11d, respectively. With this, the pixel electrodes 27 are electrically connected to the pixel electrode-side source-drain regions 30d (drain regions) of the semiconductor layers 30. It is to be noted that the pixel electrodes 27 are formed by a transparent conductive film such as an ITO film, for example.

The alignment layer 28 is provided on the pixel electrodes 27 and the third insulating interlayer 11d. The alignment layer 28 is formed by performing oblique evaporation of an inorganic material such as silicon oxide (SiO₂). The liquid crystal layer 15 obtained by injecting the liquid crystal and the like into a space surrounded by the sealing member 14 (see, FIG. 1 and FIG. 2) is provided on the alignment layer 28.

A color filter layer 41 is provided on the second base material 20a (at the liquid crystal layer 15 side). The configuration of the color filter layer 41 will be described later. The counter electrode 31 is provided on the entire surface of the color filter layer 41. The alignment layer 32 formed by performing oblique evaporation of an inorganic material such as silicon oxide (SiO₂) is provided on the counter electrode 31. For example, the counter electrode 31 is formed by a transparent conductive film such as an ITO film in the same manner as the above-mentioned pixel electrodes 27.

The liquid crystal layer 15 takes a predetermined alignment state by the alignment layers 28 and 32 in a state in which an electric field is not generated between the pixel electrodes 27 and the counter electrode 31. The sealing member 14 is an adhesive made of a thermosetting or ultraviolet-curable epoxy resin, for example. The sealing member 14 bonds the element substrate 10 and the counter substrate 20 on the peripheries thereof. A spacer such as glass fibers or glass beads for keeping a predetermined distance between the substrates is mixed into the sealing member 14.

### Configurations of Counter Substrate and Color Filter Substrate

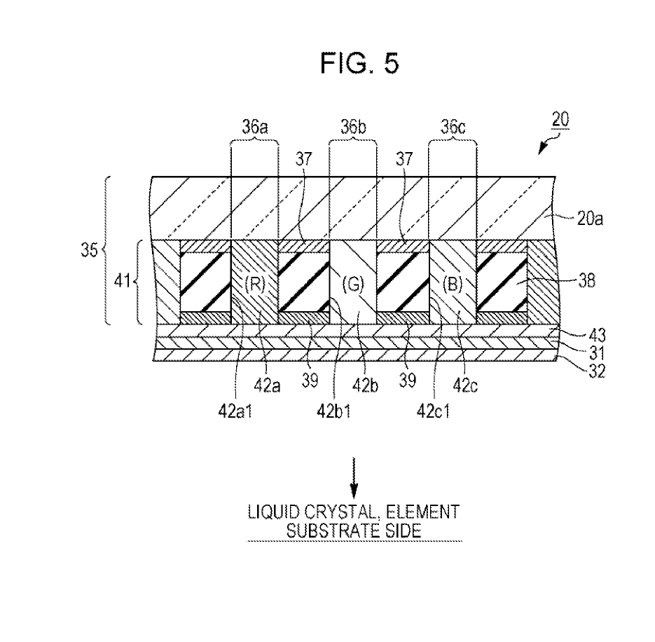

FIG. 5 is a schematic cross-sectional view illustrating configurations of the counter substrate constituting the liquid crystal device and the color filter substrate constituting the counter substrate. Hereinafter, described are the configurations of the counter substrate and the color filter substrate with reference to FIG. 5.

As illustrated in FIG. 5, a stopper film 37 is provided on the second base material 20a (liquid crystal side) constituting the counter substrate 20 of the liquid crystal device 100 on regions excluding color filter regions 36a, 36b, and 36c when seen from the above. An insulating film 38 such as a silicon oxide film (SiO₂) and a light-shielding film (BM) 39 are provided on the stopper film 37 so as to surround the color filter regions 36a, 36b, and 36c. In other words, color filter grooves 42a1, 42b1, and 42c1 are provided on the color filter regions 36a, 36b, and 36c, respectively. The color filter grooves 42a1, 42b1, and 42c1 are opening holes surrounded by a laminated film of the stopper film 37, the insulating film 38, and the light-shielding film 39.

Color filters 42a, 42b, 42c are provided in the color filter grooves 42a1, 42b1, and 42c1, respectively. An overcoat 43 made of a resin or the like having light transmissivity is provided on the color filters 42a, 42b, and 42c and the light-shielding film 39. The counter electrode 31 is provided on the overcoat 43. The alignment layer 32 formed by performing oblique evaporation of the inorganic material such as silicon oxide (SiO₂) is provided on the counter electrode 31.

### Method of Manufacturing Liquid Crystal Device as Electrooptic Device

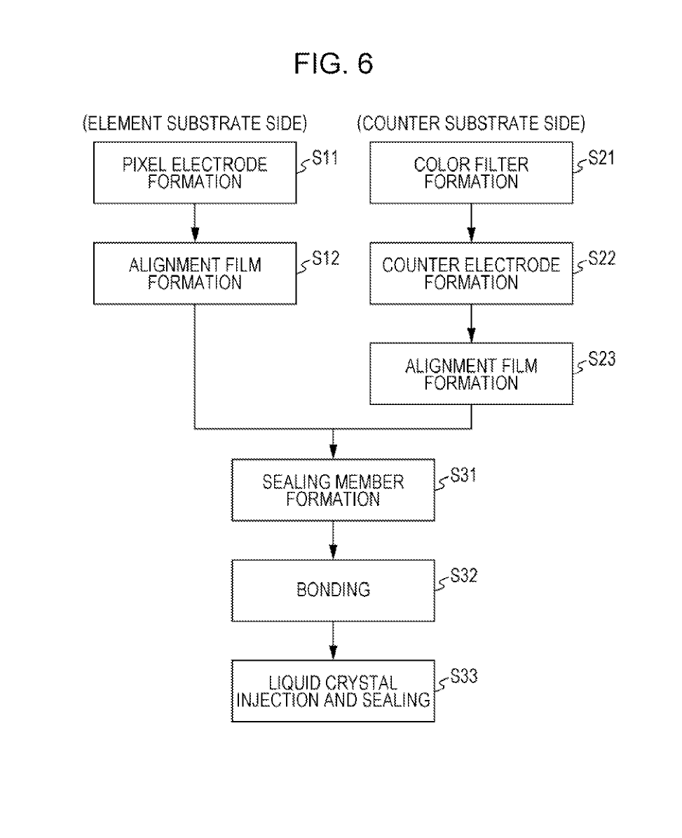

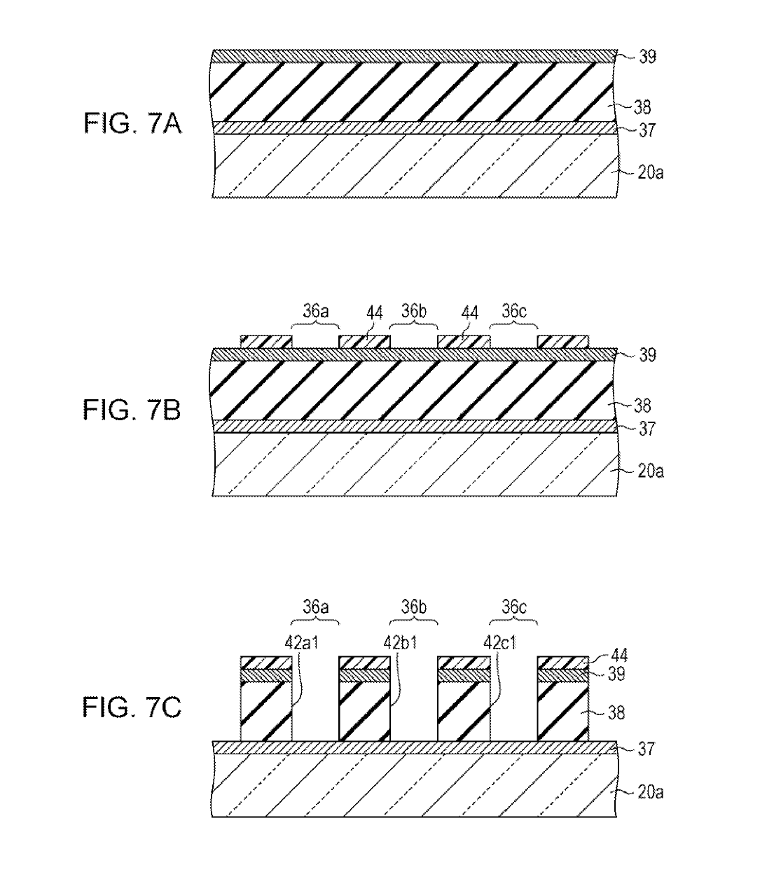

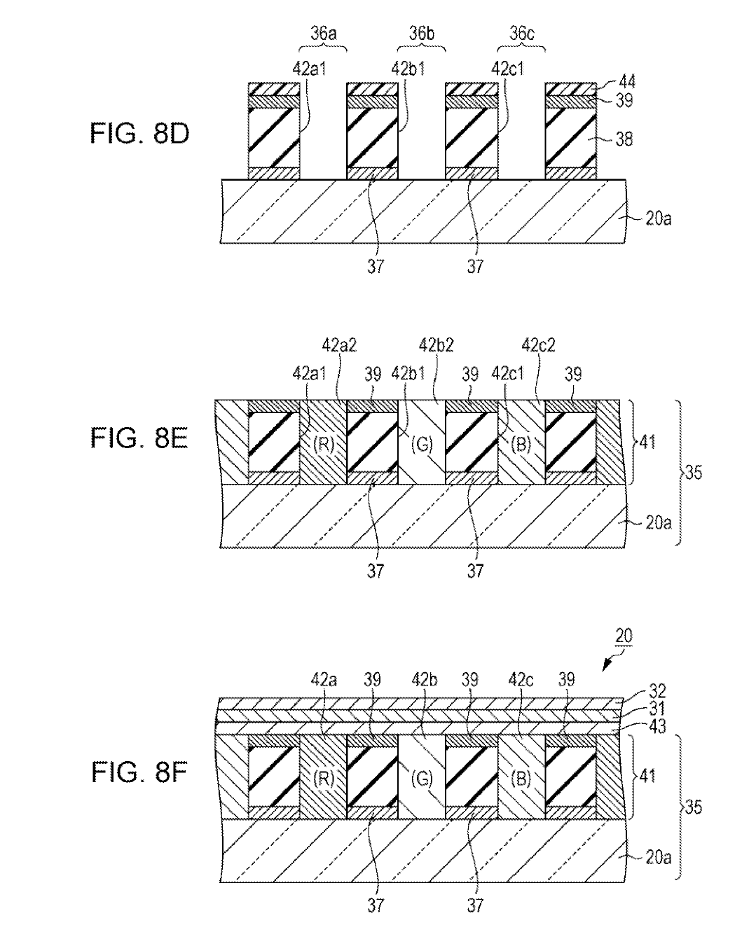

FIG. 6 is a flowchart illustrating a method of manufacturing the liquid crystal device in the order of processes. FIGS. 7A to 7C and FIGS. 8D to 8F are schematic cross-sectional views illustrating a part of the method of manufacturing the liquid crystal device. Hereinafter, described is the method of the liquid crystal device with reference to FIG. 6 to FIG. 8F.

Initially, described is a method of manufacturing the element substrate 10. Description is made while the first base material 10a to the third insulating interlayer lid are referred to as the first base material 10a. First, the pixel electrodes 27 and the like are formed on the first base material 10a made of the quartz substrate or the like by using known film formation techniques, that is, the photography technique and the etching technique at step S11.

The alignment layer 28 is formed at step S12. To be specific, the alignment layer 28 having columnar structures is formed on the entire third insulating interlayer 11d (first base material 10a) on which the pixel electrodes 27 are provided by performing oblique evaporation of the inorganic material such as silicon oxide (SiO₂).

Next, described is a method of manufacturing the counter substrate 20. First, the color filters 42a, 42b, and 42c are formed on the second base material 20a made of a light-transmissive material such as the quartz substrate at S21. Detail description is made with reference to FIGS. 7A to 7C and FIGS. 8D to 8F.

In a process (stopper film formation process, insulating film formation process) as illustrated in FIG. 7A, the stopper film 37, the insulating film 38, and the light-shielding film 39 are formed on the second base material 20a made of quartz or the like in this order. The stopper film 37 is polysilicon, for example. The thickness of the stopper film 37 is 500 Å, for example. A low pressure chemical vapor deposition (LPCVD) method is used as the method of manufacturing the stopper film 37.

The insulating film 38 is a silicon oxide film. The thickness of the insulating film 38 is 1.2 μm, for example. A plasma CVD method is used as the method of manufacturing the insulating film 38.

The light-shielding film 39 (BM) is tungsten silicide (WSi). The thickness of the light-shielding film 39 is 0.2 μm, for example. A sputtering method is used as the method of manufacturing the light-shielding film 39.

In a process as illustrated in FIG. 7B, resist patterns 44 are formed on regions excluding the regions on which the color filters 42a, 42b, and 42c are formed. To be specific, first, a resist film is formed on the light-shielding film 39. Next, the resist film is patterned by using the photolithography technique so as to form the resist patterns 44.

In a process (opening hole formation process) as illustrated in FIG. 7C, the color filter grooves 42a1, 42b1, and 42c1 are formed on the color filter regions 36a, 36b, and 36c on which the color filters 42a, 42b, and 42c are formed, respectively. To be specific, etching processing is performed on the light-shielding film 39 and the insulating film 38 by using the resist patterns 44 as masks.

An etching device employs reactive ion etching (RIE), for example. Gas that is used is CHF3, CF4, or the like. With this, the color filter grooves 42a1, 42b1, and 42c1 are formed on the color filter regions 36a, 36b, and 36c, respectively.

The stopper film 37 is provided on the second base material 20a. A selection ratio between the insulating film 38 and the stopper film 37 is approximately 10. Therefore, when the insulating film 38 is etched, etching can be adequately stopped at the stopper film 37. This can form the plurality of color filter grooves 42a1, 42b1, and 42c1 having a uniform depth.

In a process (removal process) as illustrated in FIG. 8D, the stopper film 37 is removed by etching. To be specific, the stopper film 37 is etched using the above-mentioned resist patterns 44 as masks. An etching device employs reactive ion etching (RIE), for example. With this, the color filter grooves 42a1, 42b1, and 42c1 are formed on the color filter regions 36a, 36b, and 36c, respectively. The resist patterns 44 are removed by ashing.

In a process (color filter formation process) as illustrated in FIG. 8E, the color filter layer 41 is completed. To be specific, color filter materials (coloring layers) are filled into the color filter grooves 42a1, 42b1, and 42c1. A red coloring layer (42a2), a green coloring layer (42b2), and a blue coloring layer (42c2) are formed selectively in the color filter grooves 42a1, 42b1, and 42c1, respectively, by a spin coat method, for example. Thereafter, for example, the coloring layers 42a2, 42b2, and 42c2 are heated to be cured. With this, the color filter layer 41 is completed.

At step S22 (see, FIG. 8F), the overcoat 43, the counter electrode 31 are formed on the color filter layer 41. To be specific, the overcoat 43 and the counter electrode 31 are formed by a well-known film formation technique.

At step S23 (see, FIG. 8F), the alignment layer 32 is formed on the counter electrode 31. An oblique evaporation method of performing oblique evaporation of an inorganic material such as silicon oxide (SiO₂) is used as the method of manufacturing the alignment layer 32. With this, the counter substrate 20 is completed. Next, described is a method of bonding the element substrate 10 and the counter substrate 20.

The sealing member 14 is applied onto the element substrate 10 at step S31. To be specific, for example, the sealing member 14 is applied onto the peripheral edge of the display region E on the element substrate 10 (so as to surround the display region E) while changing relative positional relation between the element substrate 10 and a dispenser (which can be a discharging device).

At step S32, the element substrate 10 and the counter substrate 20 are bonded to each other. To be specific, the element substrate 10 and the counter substrate 20 are bonded to each other through the sealing member 14 applied onto the element substrate 10. To be more specific, the element substrate 10 and the counter substrate 20 are bonded while ensuring two-dimensional positional accuracy of the substrates 10 and 20 in the lengthwise direction and the width direction.

At step S33, the liquid crystal is injected into the structure through a liquid crystal injection port, and then, the liquid crystal injection port is sealed by a sealing material. With this, the liquid crystal device 100 is completed.

### Configuration of Electronic Apparatus

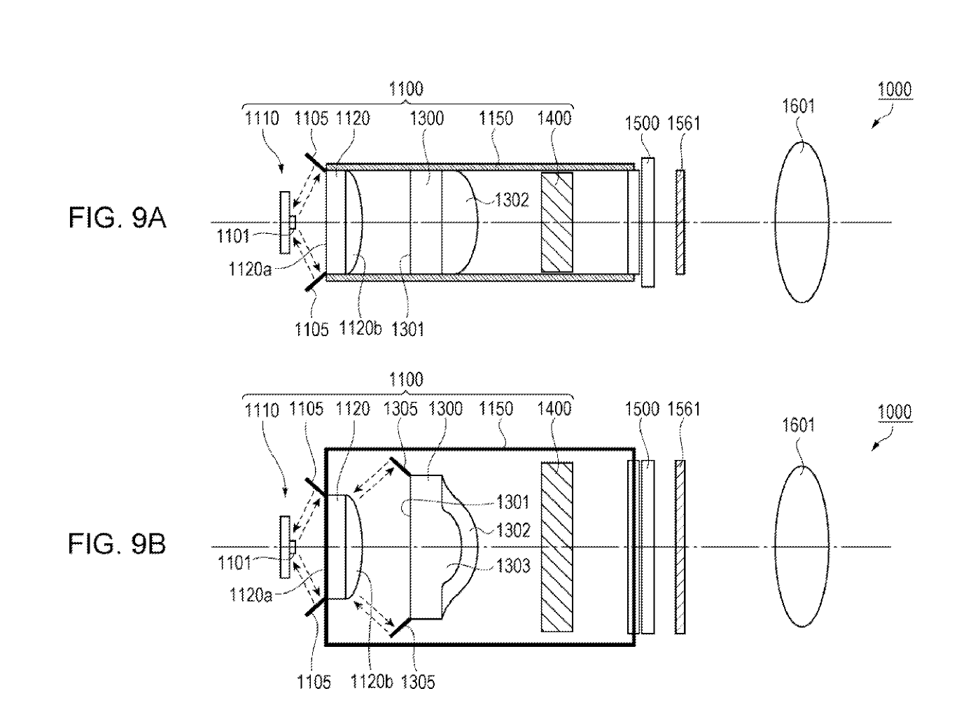

Next, described is a projection-type display apparatus as an electronic apparatus in the embodiment with reference to FIGS. 9A and 9B. FIGS. 9A and 9B are schematic views illustrating a configuration of the projection-type display apparatus including the above-mentioned liquid crystal device. FIG. 9A is a schematic side cross-sectional view and FIG. 9B is a schematic cross-sectional view when seen from the above.

As illustrated in FIGS. 9A and 9B, a projection-type display apparatus 1000 as the electronic apparatus in the embodiment includes an illumination device 1100, a liquid crystal light valve 1500 as a light modulation unit, and a projecting lens 1601 as a projecting optical system. The above-mentioned liquid crystal device 100 is applied to the liquid crystal light valve 1500. The liquid crystal light valve 1500 modulates illumination light output from the illumination device 1100 based on image information and converts it to display light. The converted display light is output from the liquid crystal light valve 1500 so as to be projected onto a screen, for example, by the projecting lens 1601.

The illumination device 1100 in the embodiment is configured by including a second condensing lens 1300, a polarizing beam splitter 1400, and a light-shielding box 1150 in addition to respective constituent components of a light emitting element 1110, a first condensing lens 1120, and reflection members 1105. The light-shielding box 1150 accommodates the first condensing lens 1120, the second condensing lens 1300, and the polarizing beam splitter 1400 such that light from the outside is not incident on the liquid crystal light valve 1500.

A light emitting diode (LED) 1101 as a solid state light source on the light emitting element 1110, the first condensing lens 1120, the second condensing lens 1300, the polarizing beam splitter 1400, the liquid crystal light valve 1500, and the projecting lens 1601 are arranged on the same optical axis (light axis).

The second condensing lens 1300 includes a flat input surface 1301 and a lens portion 1302. The input surface 1301 has an opening diameter larger than that of an input surface 1120a of the first condensing lens 1120. The lens portion 1302 is convex with respect to the input surface 1301. Further, the second condensing lens 1300 is out-of-round when seen from the optical axis direction and has cut surfaces 1303 by cutting upper and lower sides thereof. The cut surfaces 1303 make contact with the above-mentioned light-shielding box 1150.

The second condensing lens 1300 is arranged on the optical axis such that the input surface 1301 of light opposes to a lens portion 1120b of the first condensing lens 1120. Further, the second condensing lens 1300 includes reflecting members 1305. The reflecting members 1305 retroreflect non-effective light of light that has been output from the light emitting element 1110 and collected by the first condensing lens 1120 to the lens portion 1120b of the first condensing lens 1120. The non-effective light is light that is not incident on the input surface 1301 of the second condensing lens 1300.

The reflecting members 1305 have the same configuration as the reflecting members 1105 and have a plurality of retroreflective bodies on reflecting surfaces thereof. An arrangement pitch of the retroreflective bodies is equal to or larger than 5 μm and equal to or smaller than 100 μm. As illustrated in FIG. 9B, the reflecting members 1305 are provided so as to make contact with the outer edges of the second condensing lens 1300 at right and left sides when seen from the optical axis direction. It is sufficient that the reflecting members 1305 are arranged at the following positions between the first condensing lens 1120 and the second condensing lens 1300. That is, it is sufficient that the reflecting members 1305 are arranged at the positions at which they do not inhibit the light incident on the input surface 1301 and retroreflect at least a part of the non-effective light which is not incident on the input surface 1301 to the lens portion 1120b of the first condensing lens 1120.

The polarizing beam splitter 1400 converts the light collected by the second condensing lens 1300 to polarized light (S waves). The polarizing beam splitter 1400 is arranged at the light incident side and a light polarizing element 1561 is arranged at the light output side.

According to the above-mentioned projection-type display apparatus 1000, the liquid crystal device 100 having the improved transmittance is used as the liquid crystal light valve 1500, thereby achieving high display quality.

As the electronic apparatus on which the liquid crystal device 100 is mounted, there are various types of electronic apparatuses such as an electrical view finder (EVF), and a mobile mini projector (pico projector) in addition to the projection-type display apparatus 1000.

As described in detail above, with a color filter substrate 35, the liquid crystal device 100, the method of manufacturing the liquid crystal device 100, and the electronic apparatus in the first embodiment, the following effects are obtained.

1. With the color filter substrate 35, the liquid crystal device 100, and the method of manufacturing the liquid crystal device 100 in the first embodiment, the stopper film 37 is formed on the second base material 20a. Therefore, when the color filter grooves 42a1, 42b1, and 42c1 are formed on the insulating film 38 on the stopper film 37, the etching can be adequately stopped at the stopper film 37 based on the selection ratio between the insulating film 38 and the stopper film 37. With this, the plurality of color filter grooves 42a1, 42b1, and 42c1 can be formed to have a predetermined depth. When the color filters 42a, 42b, and 42c are formed in the color filter grooves 42a1, 42b1, and 42c1, respectively, the color filters 42a, 42b, and 42c can be prevented from projecting from the insulating film 38. This can make a gap between the element substrate 10 and the counter substrate 20 uniform over the entire substrate. As a result, influence on the transmittance and the like can be suppressed.

2. With the color filter substrate 35, the liquid crystal device 100, and the method of manufacturing the liquid crystal device 100 in the first embodiment, the light-shielding film 39 is provided on the insulating film 38, that is, on the regions excluding the color filter grooves 42a1, 42b1, 42c1. This can suppress entrance of oblique light into the color filters 42a, 42b, and 42c.

3. With the electronic apparatus in the first embodiment, the electronic apparatus includes the above-mentioned liquid crystal device 100. This can provide an electronic apparatus capable of improving display quality such as the transmittance and the like.

### Second Embodiment

### Configuration of Counter Substrate and Color Filter Substrate

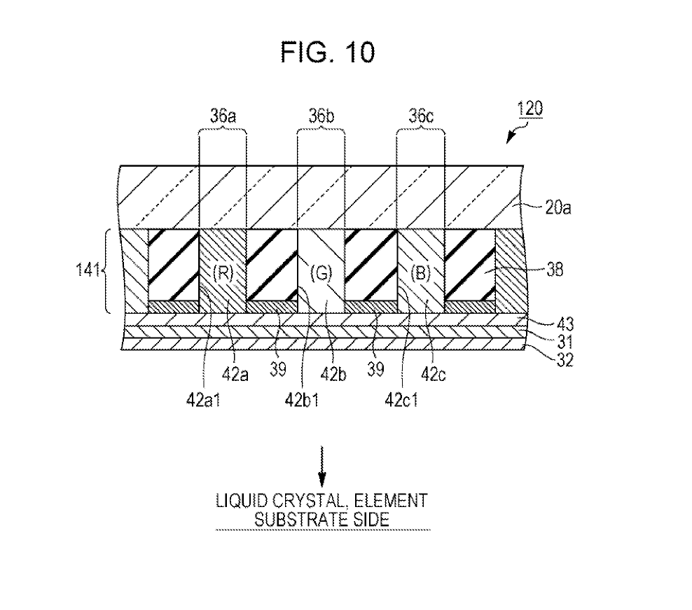

FIG. 10 is a schematic cross-sectional view illustrating configurations of a counter substrate constituting a liquid crystal device and a color filter substrate constituting the counter substrate in a second embodiment. Hereinafter, described are configurations of the counter substrate and the color filter substrate with reference to FIG. 10.

A color filter layer of a counter substrate 120 in the second embodiment has a different configuration from that in the above-mentioned first embodiment. Other configurations in the second embodiment are substantially the same as those in the above-mentioned first embodiment. Therefore, in the second embodiment, portions that are different from the first embodiment are described in detail and description of other overlapped portions is omitted appropriately.

As illustrated in FIG. 10, on the counter substrate 120 in the second embodiment, the color filters 42a, 42b, and 42c are provided on the color filter regions 36a, 36b, and 36c on the second base material 20a, respectively. The insulating film 38 such as a silicon oxide film (SiO₂) and the light-shielding film 39 are provided on the regions excluding the color filter regions 36a, 36b, and 36c on the second base material 20a so as to surround the color filter regions 36a, 36b, and 36c.

As in the first embodiment, the overcoat 43 made of a resin or the like having light transmissivity is provided on a color filter layer 141. The counter electrode 31 is provided on the overcoat 43. The alignment layer 32 formed by performing oblique evaporation of the inorganic material such as silicon oxide (SiO₂) is provided on the counter electrode 31.

The counter substrate 120 is different from the counter substrate 20 in the first embodiment in a point that the stopper film 37 is not provided on the regions excluding the color filter regions 36a, 36b, and 36c when seen from the above. Thus, the stopper film 37 is not provided on the counter substrate 120. Therefore, the transmittance can be improved in comparison with the liquid crystal device 100 in the first embodiment.

Method of Manufacturing Counter Substrate (Color Filter Substrate)

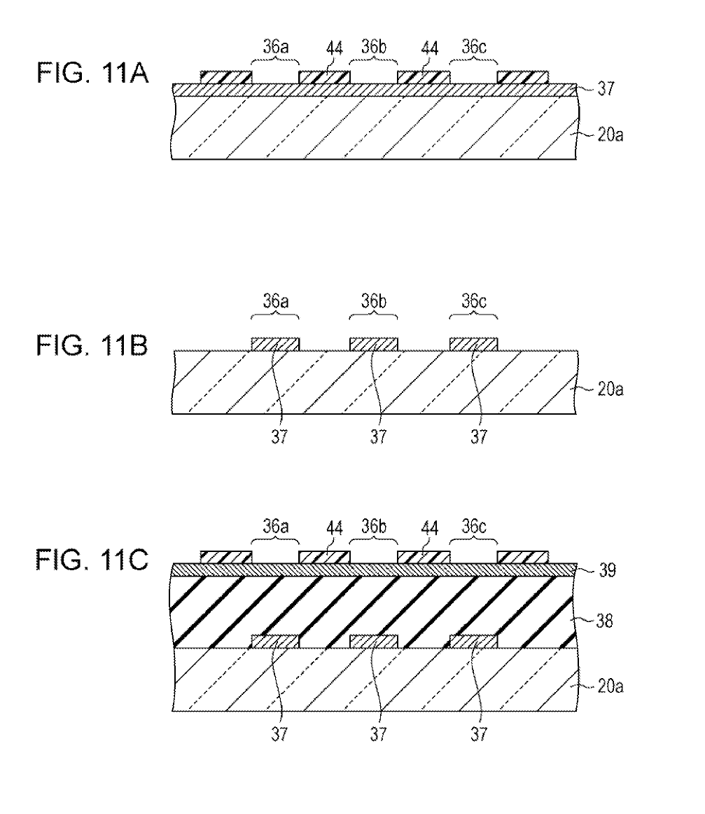

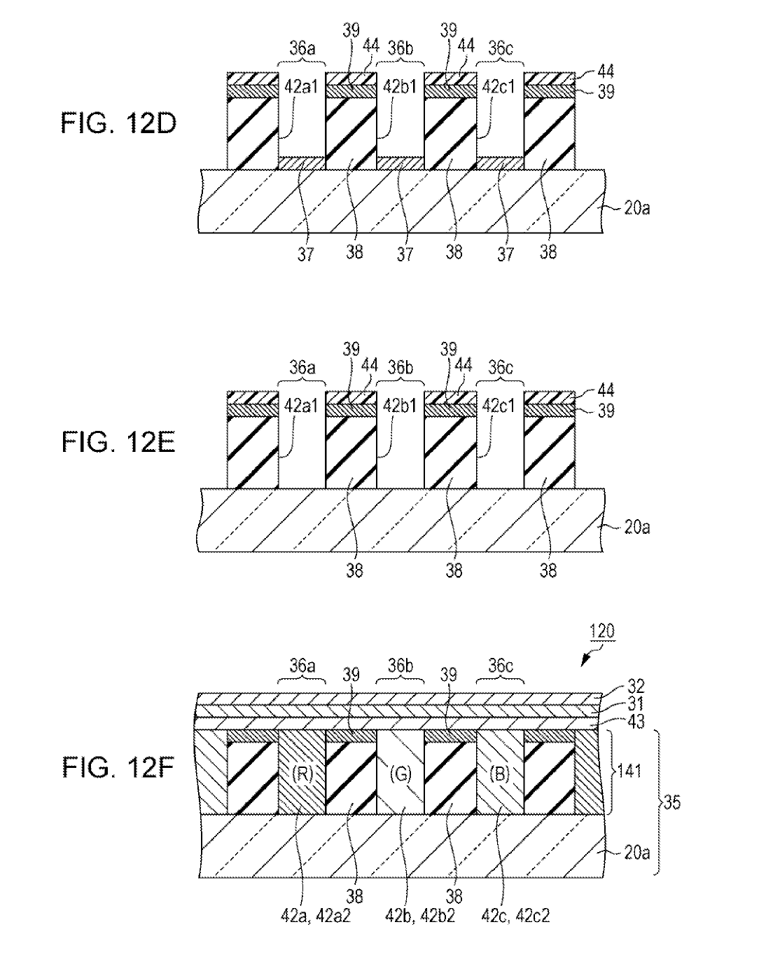

FIGS. 11A to 11C and FIGS. 12D to 12F are schematic cross-sectional views illustrating a method of manufacturing the counter substrate in the second embodiment in the order of processes. Hereinafter, described is the method of manufacturing the counter substrate with reference to FIGS. 11A to 11C and FIGS. 12D to 12F.

In a process as illustrated in FIG. 11A, the stopper film 37 and the resist patterns 44 are formed on the second base material 20a made of quarts or the like. To be specific, the stopper film 37 is formed on the second base material 20a, and then, the resist patterns 44 are formed on the stopper film 37 on the regions excluding the color filter regions 36a, 36b, and 36c when seen from the above by using the photography technique.

In a process as illustrated in FIG. 11B, the stopper film 37 is patterned. To be specific, etching processing is performed on the stopper film 37 using the resist patterns 44 as masks. With this, the stopper film 37 is patterned on the color filter regions 36a, 36b, and 36c. The resist patterns 44 are removed by ashing.

In a process as illustrated in FIG. 11C, preparation for forming the color filter grooves 42a1, 42b1, and 42c1 on the color filter regions 36a, 36b, and 36c, respectively, is made. To be specific, first, the insulating film 38 is formed on the stopper film 37 and the second base material 20a by using the plasma CVD method. Subsequently, the light-shielding film 39 is formed on the insulating film 38 by using the sputtering method. Thereafter, the resist patterns 44 are formed on the light-shielding film 39 on the regions excluding the color filter regions 36a, 36b, and 36c when seen from the above by using the photolithography technique and the like.

In a process as illustrated in FIG. 12D, a part of the color filter grooves 42a1, 42b1, and 42c1 are formed on the color filter regions 36a, 36b, and 36c, respectively. To be specific, etching processing is performed on the light-shielding film 39 and the insulating film 38 by using the resist patterns 44 as masks. With this, the color filter grooves 42a1, 42b1, and 42c1 surrounded by the light-shielding film 39 and the insulating film 38 are formed on the color filter regions 36a, 36b, and 36c, respectively.

It is to be noted that the stopper film 37 is formed on the regions overlapping with the color filter regions 36a, 36b, and 36c when seen from the above previously. Therefore, when the etching processing is performed, etching can be stopped at the stopper film 37. This can form the plurality of color filter grooves 42a1, 42b1, and 42c1 having a substantially uniform depth.

In a process as illustrated in FIG. 12E, the stopper film 37 is removed. To be specific, the counter substrate 120 is set on a device of etching polysilicon and etching processing is performed on the stopper film 37 by using the resist patterns 44 as masks. With this, the color filter grooves 42a1, 42b1, and 42c1 on which the stopper film 37 is not formed are formed on the color filter regions 36a, 36b, and 36c, respectively. The resist patterns 44 are removed by ashing.

In a process as illustrated in FIG. 12F, the color filter substrate 35 and the counter substrate 120 are completed. To be specific, first, color filter materials (coloring layers) are filled into the color filter grooves 42a1, 42b1, and 42c1. The red coloring layer 42a2, the green coloring layer 42b2, and the blue coloring layer 42c2 are formed selectively in the color filter grooves 42a1, 42b1, and 42c1, respectively, by using a spin coat method, for example. Thereafter, for example, the coloring layers 42a2, 42b2, and 42c2 are heated to be cured. With this, the color filter layer 141 is completed.

Thereafter, the overcoat 43, the counter electrode 31, and the alignment layer 32 are formed on the color filter layer 141. The methods of manufacturing them are the same as those in the first embodiment. With this, the counter substrate 120 is completed.

As described in detail above, with the color filter substrate 35, the liquid crystal device, the method of manufacturing the liquid crystal device, and the electronic apparatus in the second embodiment, the following effects are obtained in addition to the above-mentioned effects 1, 2, and 3.

4. According to the color filter substrate 35, the liquid crystal device, and the method of manufacturing the liquid crystal device in the second embodiment, the stopper film 37 is formed only on the color filter regions 36a, 36b, and 36c on the second base material 20a. Therefore, when the color filter grooves 42a1, 42b1, and 42c1 are formed, etching can be stopped at the predetermined depth by the stopper film 37. Further, after the color filter grooves 42a1, 42b1, and 42c1 are formed, the stopper film 37 is exposed in the color filter grooves 42a1, 42b1, and 42c1. Therefore, the stopper film 37 influencing on the aperture ratio can be removed from the second base material 20a. As a result, the stopper film 37 is not formed on the second base material 20a, thereby improving the aperture ratio.

The aspects of the invention are not limited to the above-mentioned embodiments and can be changed appropriately within a range without departing from the scope or the spirit of the invention that can be read from the scope of the invention and the specification overall. The variations are encompassed in the technical range of the aspects of the invention. Further, the invention can be also executed in the following modes.

### Variation 1

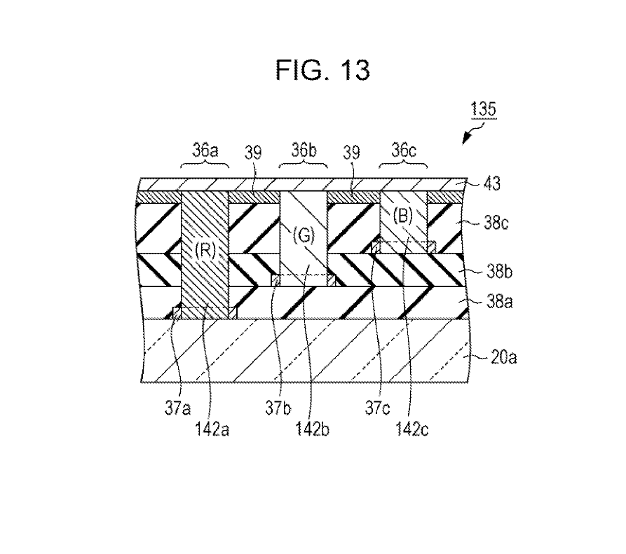

Instead of the above-mentioned configuration in which the color filter grooves 42a1, 42b1, and 42c1 are set to have the same depth for the respective colors (red, green, blue), the color filter grooves may have different depths depending on the colors as those in a color filter substrate 135 as illustrated in FIG. 13. FIG. 13 is a schematic cross-sectional view illustrating a configuration of the color filter substrate in a variation. The color filter substrate 135 as illustrated in FIG. 13 is provided with a first insulating film 38a, a second insulating film 38b, a third insulating film 38c, the light-shielding film 39, and the overcoat 43 in this order from the second base material 20a side.

A stopper film 37a for red is provided on the color filter region 36a for red on the second base material 20a. A stopper film 37b for green is provided on the color filter region 36b for green on the first insulating film 38a. Further, a stopper film 37c for blue is provided on the color filter region 36c for blue on the second insulating film 38b. That is to say, the stopper films 37a, 37b, and 37c are arranged such that spaces between the second base material 20a and the stopper films 37a, 37b, and 37c are different in the normal line direction of the second base material 20a.

A color filter 142a for red that transmits red light selectively is provided on the stopper film 37a for red so as to penetrate through the first insulating film 38a, the second insulating film 38b, and the third insulating film 38c. A color filter 142b for green that transmits green light selectively is provided on the stopper film 37b for green so as to penetrate through the second insulating film 38b and the third insulating film 38c. A color filter 142c for blue that transmits blue light selectively is provided on the stopper film 37c for blue so as to penetrate through the third insulating film 38c.

The upper surfaces of the insulating films 38a, 38b, and 38c may be flattened using a polishing method such as chemical mechanical polishing (CMP). Further, the stopper films 37a, 37b, and 37c on the regions overlapping with the color filter regions 36a, 36b, and 36c for the respective colors when seen from the above form the color filter grooves, and then, are removed by etching.

The light-shielding film 39 is provided on the third insulating film 38c between the adjacent color filter regions 36a, 36b, and 36c for the respective colors. It is to be noted that the color filter substrate 135 may have a configuration in which the light-shielding film 39 is not provided. Further, the colors are not limited to red (R), green (G), and blue (B), and a white color filter (color filter groove has a depth narrower than those for other colors) for increasing an intensity of white (W) may be provided. In the above-mentioned first embodiment and second embodiment, configurations in which the white color filter is provided may be also employed.

In this manner, in accordance with the colors of the color filters 142a, 142b, and 142c, the thicknesses (spaces) of the insulating films 38a, 38b, and 38c are controlled and the positions of the stopper films 37a, 37b, and 37c are made different so as to change optical path lengths (thicknesses of the color filters 142a, 142b, and 142c). With this, the intensity of red is increased on the color filter region 36a for red, the intensity of green is increased on the color filter region 36b for green, and the intensity of blue is increased on the color filter region 36c for blue. That is to say, the degree of purity can be made higher for the respective colors (hues can be improved), thereby improving display quality.

### Variation 2

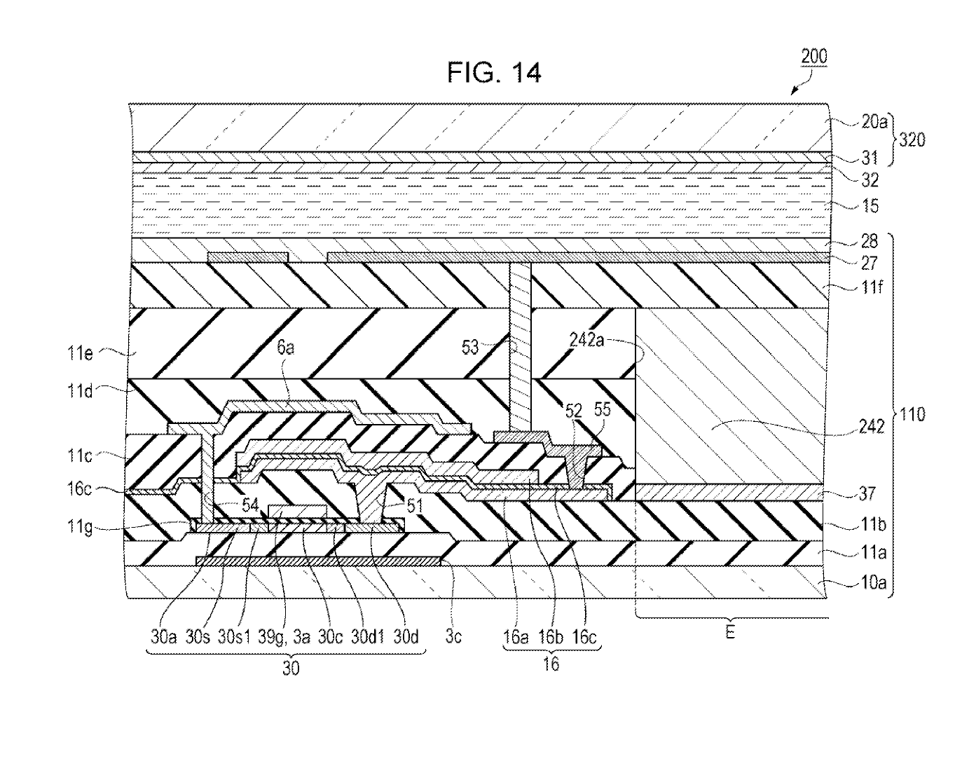

The invention is not limited to the configuration in which the color filters 42a, 42b, and 42c are provided on the counter substrate 20 as described above and color filters 242 may be provided on an element substrate 110 as illustrated in FIG. 14, for example. FIG. 14 is a schematic cross-sectional view illustrating a configuration of a liquid crystal device 200 according to a variation. It is to be noted that the liquid crystal device 200 has a color filter on array (COA) structure.

As illustrated in FIG. 14, in the liquid crystal device 200 in the variation, the foundation insulating layer 11a, a first insulating interlayer 11b to a fourth insulating interlayer 11e, and a passivation layer 11f are laminated on the first base material 10a. The TFTs 30 are provided on the foundation insulating layer 11a. Further, the capacitor elements 16 are provided on the first insulating interlayer 11b.

For example, the color filters 242 are provided on the second insulating interlayer 11c to the fourth insulating interlayer 11e on the display region E. For example, the stopper film 37 for defining the depths of color filter grooves 242a is provided on the first insulating interlayer 11b in the same manner as in the above-mentioned embodiments. The TFTs 30, the capacitor elements 16, the data lines 6a, and the like are provided between the color filters 242.

The pixel electrodes 27 are provided on the passivation layer 11f. For example, the alignment layer 28 formed by performing oblique evaporation of the inorganic material such as silicon oxide (SiO₂) is provided on the pixel electrodes 27 and the passivation layer 11f.

On the other hand, the counter electrode 31 is provided on the entire surface of the second base material 20a. The alignment layer 32 formed by performing oblique evaporation of the inorganic material such as silicon oxide (SiO₂) is provided on the counter electrode 31 (liquid crystal layer 15 side).

### Variation 3

The electrooptic device is not limited to be applied to the liquid crystal device 100 as described above. For example, the electrooptic device may be applied to an organic electroluminescent (EL) device, a plasma display, an electronic paper, and the like, for example.

The entire disclosure of Japanese Patent Application No. 2013-034262, filed Feb. 25, 2013 is expressly incorporated by reference herein.

What is claimed is:

1. A color filter substrate comprising:
a substrate;
a first stopper film that is disposed on the substrate;
an insulating film that has a first opening disposed on the first stopper film; and
a first color filter that is disposed in the first opening.

2. The color filter substrate according to claim 1, further comprising:
a second color filter that is disposed in a second opening of the insulating film.

3. The color filter substrate according to claim 2, further comprising:
a second stopper film that is disposed between the second color filter and the substrate,
a first space between the substrate and the first stopper film being different from a second space between the substrate and the second stopper film.

4. The color filter substrate according to claim 1,
the first stopper film being disposed so as not to overlap with the first opening when seen from above.

5. The color filter substrate according to claim 1,
a light-shielding film being disposed on the insulating film.

6. An electrooptic device comprising:
a first substrate;
a second substrate that is arranged so as to oppose to the first substrate;
an electrooptic layer that is held between the first substrate and the second substrate;
a first stopper film that is disposed on the first substrate or the second substrate;
an insulating film that has a first opening disposed on the stopper film; and
a first color filter that is disposed in the first opening.

7. The electrooptic device according to claim 6, further comprising:
a second color filter that is disposed in a second opening of the insulating film.

8. The electrooptic device according to claim 7, further comprising:
a second stopper film that is disposed between the second color filter and the substrate,
a first space between the first substrate or the second substrate and the first stopper film being different from a second space between the first substrate or the second substrate and the second stopper film.

9. The electrooptic device according to claim 6,
the first stopper film being disposed so as not to overlap with the first opening when seen from above.

10. The electrooptic device according to claim 6,
a light-shielding film being disposed on the insulating film.

11. An electronic apparatus comprising the electrooptic device according to claim 5.

12. An electronic apparatus comprising the electrooptic device according to claim 6.

13. An electronic apparatus comprising the electrooptic device according to claim 7.

14. An electronic apparatus comprising the electrooptic device according to claim 8.
